(19) United States
(12) Patent Application Publication
(10) Pub. No.: US 2004/0187051 A1
(43) Pub. Date: Sep. 23, 2004

(54) Memory error generating method, apparatus and computer program product

(75) Inventors: Robert Walter Berry JR., Round Rock, TX (US); Robert Christopher Dixon, Austin, TX (US); Resham Rajendra Kulkarni, Austin, TX (US); Pedro Martin-de-Nicolas, Austin, TX (US)

Correspondence Address: Robert M. Carwell, International Business Machines Corporation, Intellectual Property Law Dept., Internal Zip 4054, 11400 Burnet Road,, Austin, TX, 78758, US

(73) Assignee: International Business Machines Corporation, Armonk, NY

(21) Appl. No.: 10/392,759

(22) Filed: Mar. 20, 2003

(51) Int. Cl. G11C 29/00

(52) U.S. Cl. 714/718

(57) ABSTRACT

In one form of the invention, an apparatus has a first switch operable in an error injection state for interrupting a transfer of first data from a memory device to a test system, and in a normal state for permitting unimpeded data transfer. The apparatus has a second switch operable in an error injection state for sending second data to the test system instead of corresponding bits of the first data. Logic circuitry of the apparatus reads the first data and controls an error injection sequence that includes switching the first and second switches from their respective normal states to their respective error injection states responsive to receiving the command. The apparatus determines whether at least one of the corresponding data bits of the first and second data have disparate logic states independently of switching the first and second switches back to their respective normal states.

### BACKGROUND OF THE INVENTION

1. Field of the Invention

The present invention relates to testing for electronic devices, and more particularly to a method and tool for validating a test system.

2. Related Art

Virtually all electronic devices have integrated circuits (IC's), which undergo testing during the manufacturing process. FIG. 1 illustrates a typical test setup for testing IC's. The test setup includes a target device 110 having a memory coupled by a bus 115 to a test system 120 performing the test. (Herein, the target device 110 is also referred to as a memory device 110.) The test system 120, which typically includes a computer, tests the memory device 110 by applying predefined, internally generated test patterns to the memory device 110 and observing response patterns to determine if the memory device 110 has passed or failed. With increasing reliabilities and decreasing failure rates that are often measured in parts per billion, the test system 120 may operate for several days or weeks without detecting a failure.

For quality assurance purpose it is often required to verify or validate the performance of the test setup. Thus, the test system 120 itself requires validation that needs to be performed on a periodic or on-demand basis to assure its proper functioning. The proper operation of the test system 120 is typically verified by conducting a test of the test system 120. A fault inserter device 130 shown coupled to the bus 115, the memory device 110 and the test system 120, is typically added in the test setup to artificially insert an external fault for testing the test system 120.

FIGS. 2A and 2B illustrate well-known fault insertion techniques that are typically included in the fault inserter device 130. In FIG. 2A, conventional logic 201 is shown for inserting a fault in a data bit line 202, which may be, for example, a line of bus 115 (FIG. 1). Logic 201 has an exclusive OR gate 220 with a first input 205 and an output 215 inserted in series in the line 202. A second input 210 is for receiving a signal to inject an error. Responsive to the error signal asserted on input 210, the gate 220 outputs a complement of input 205 on output 215. Thus, regardless of the logic value of the signal on input 205 output 215 will be the complement. Thus, from the viewpoint of a device expecting to receive the logic state of the signal on the input 205, regardless of whatever state that may be the output 215 value will be in error.

In FIG. 2B, the test system 120 is coupled to the memory device 110 for testing purposes by circuit 240. The circuit 240 includes a pair of cross coupled drivers 250 and 260, the operation of which is controlled by a read or write enable signal 270. A fault is inserted by asserting a fault insertion signal on input 210 to the logic 201, which is coupled in series with the driver 260 on bit line 202.

It is disadvantageous that active components, such as components in logic 201, typically result in slowing down the performance of the test systems 120 due to their inherent gate delay. It is common also to use flip-flops, which also contributes to delay due to wait states. With increasing bus speeds and faster clock speeds of IC's, it is becoming more difficult to inject faults or errors into IC's such as memory device 110 for test purposes without introducing undesirable delays.

Additionally, traditional fault insertion techniques may have little control over the exact location of the inserted fault. For example, in testing memory devices, a traditional fault insertion technique may insert an error into an instruction area as data since there is no address mapping or linkage to the software system. In memory systems that do not detect memory errors e.g., a memory device without parity, it would be desirable to have fault insertion techniques that inject errors only into the test data.

From the above it should be appreciated that there is an increasing need to provide a fault insertion technique that improves the performance of test systems.

### SUMMARY OF THE INVENTION

The forgoing need is addressed by the present invention. In one aspect of the invention, an apparatus has a first switch operable in an error injection state for interrupting a transfer of first data from a memory device to a test system, and in a normal state for permiting unimpeded data transfer. The apparatus has a second switch operable in an error injection state for sending second data to the test system instead of corresponding bits of the first data. Logic circuitry of the apparatus reads the first data and controls an error injection sequence that includes switching the first and second switches from their respective normal states to their respective error injection states responsive to receiving the command. The apparatus determines whether at least one of the corresponding data bits of the first and second data have disparate logic states independently of switching the first and second switches back to their respective normal states.

The invention is advantageous in that it reduces the delay typically otherwise caused by the use of active components. Additionally, it is advantageous in that the fault insertion of the present invention provides a deterministic response. Additional aspects, objects, advantages and other forms of the invention will become apparent upon reading the following detailed description and upon reference to the accompanying drawings.

### BRIEF DESCRIPTION OF THE DRAWINGS

FIG. 1, described above, illustrates a typical test setup for testing integrated circuits, according to the prior art.

FIGS. 2A and 2B, described above, illustrate fault insertion techniques to inject errors, according to the prior art.

FIG. 3, illustrates a block diagram of components included in a test validation system, according to one embodiment of the present invention.

FIG. 4 shows details of an internal state machine of an error injector, according to an embodiment of the present invention.

FIGS. 5 and 6 illustrate timing diagrams for injecting an error, according to an embodiment of the present invention.

FIG. 7 is a flow chart illustrating a method for controlling an error injection sequence, according to an embodiment of the present invention.

FIG. 8 is a computer system appropriate for implementing one or more embodiments of the present invention.

### DETAILED DESCRIPTION OF A PREFERRED EMBODIMENT

The claims at the end of this application set out novel features which applicant believes are characteristic of the invention. The invention, a preferred mode of use, objectives and advantages, will best be understood by reference to the following detailed description of an illustrative embodiment read in conjunction with the accompanying drawings.

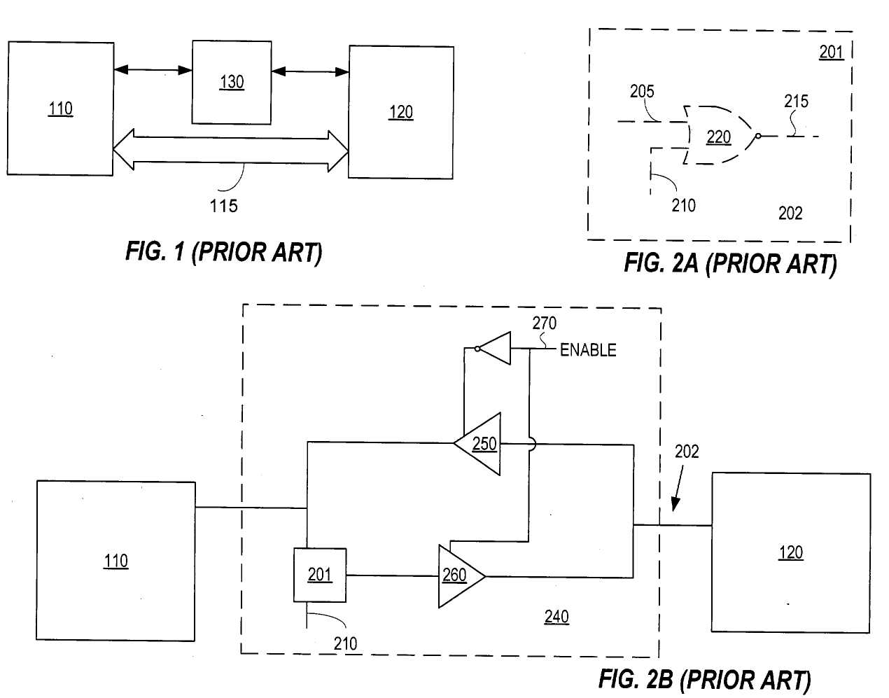

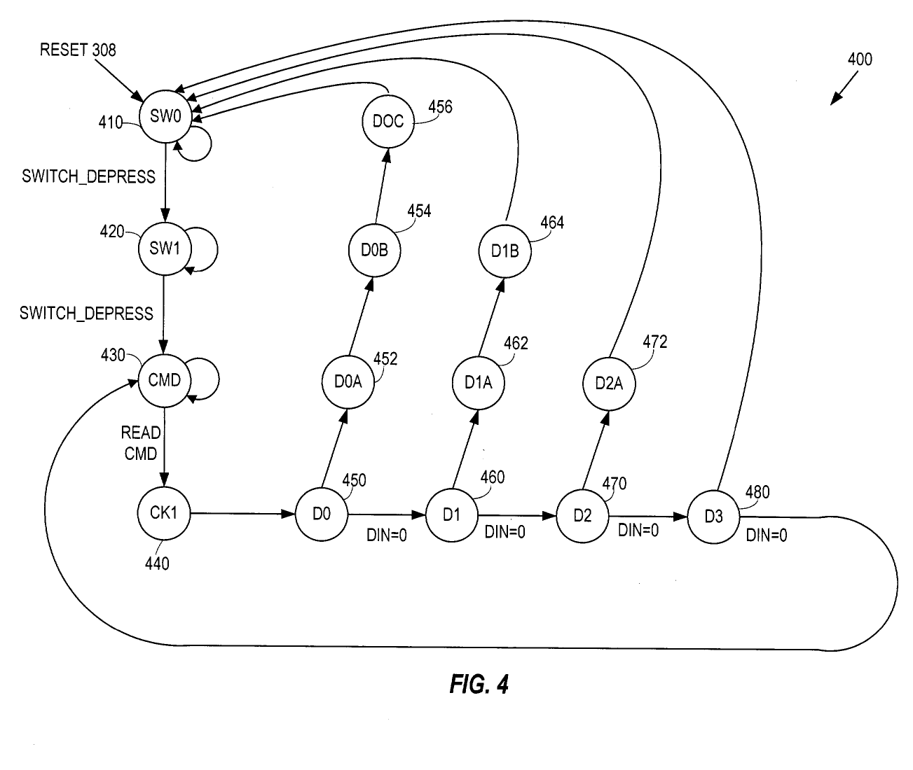

Referring to FIG. 3 in combination with FIG. 1, a block diagram illustrating components included in a test validation system 300 is shown, according to one embodiment. Components of the test validation system 300 include the test system 120, the memory device 110, logic circuitry 310, a data bit line 202 coupled to a data input 306 of the logic circuitry 310, four other bit lines 335 coupled to a command input 304 of the circuitry 310, first and second switches 320 and 330 coupled to respective outputs 312 and 314 of the circuitry 310, and a clock input 350.

The first switch 320 is coupled in series with the bit line 202 and the second switch 330 is coupled from ground to the bit line 202. The switches 320 and 330 are shown in FIG. 3 in their, normal states, in which they do not disrupt data transfer on the line 202. In their respective opposite, error-injection states the first switch 320 interrupts data transfer from the memory 110 to the system 120 on the bit line 202 and the second switch 330 pulls to ground the portion of the line 202 coupled to the system 120, referred to herein as node Dout 331 (FIG. 3).

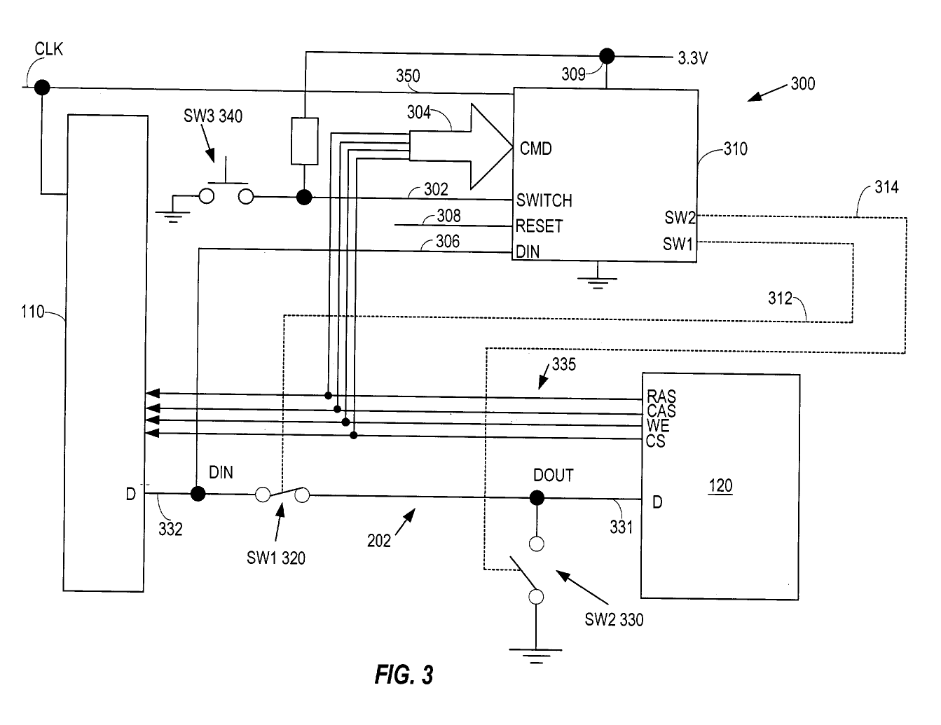

The logic circuitry 310 is operable to validate the test system 120 by injecting one or more errors in data on bit line 202, in order to see whether the test system 120 detects the errors. Specifically, the logic circuitry 310 is operable to inject errors by deterministically i) operating the switches 320 and 330 responsive to signals asserted on respective outputs 312 and 314, and then ii) returning the switches 320 and 330 to their normal positions. This is advantageous because the switches 320 and 330 introduce substantially no delay in data transfer from memory 110 to the test system 120, particularly in comparison to the more conventional logic 201 (FIGS. 2A and 2B). Therefore, the present embodiment is compatible with very high speed data transfer.

While the switches 320 and 330 are in their error injecting states the logic circuitry 310 reads the data from the memory 110 on data input 306. Then, the logic circuitry 310 checks the data to see whether the operation of the switches has injected an error.

In an embodiment, the switch 320 and 330 operation is deterministic because although the logic circuitry 310 checks the data while the switches 320 and 330 are in their error injecting states to see whether the operation of the switches has injected an error, nevertheless the logic circuitry 310 returns the switches 320 and 330 to their normal positions after a predetermined number of data bits are detected (and read) independently of whether an error was successfully injected.

The following are additional details concerning aspects of the embodiment described immediately above. As described in FIG. 1, the test system 120 includes a computer program for testing the memory device 110. The computer program writes predefined, internally generated test patterns to the memory device 110 and reads back the response patterns to determine if they are the same as the patterns that were written, in which case the memory device 110 has passed. The bit line 202 is a line of data bus 115 (not shown in FIG. 3). The bus 115 supports bi-directional data transfers between the test system 120 and the memory device 110.

The data bus 115, which includes multiple bit lines such as line 202, may be of a variable width, e.g., 128-bit, 64-bit or 32-bit, depending on the application. Each bit line represents a data path for transferring binary data. The bit line 202 shown is one of such multiple bit lines included in the data bus 115. The bit line 202 is operable to bi-directionally transfer binary data between the test system 120 and the memory device 110. The data flow on the bit line 202 may be interrupted by the operation of the first switch 320, which is inserted in series with the bit line 202.

In the illustrated embodiment, the four bit lines 335 are also included in the multiple bit lines of the data bus 115 and are operable to send and/or receive commands or instructions between the test system 120 and the memory device 110. In this embodiment, the bit lines 335 are operable to assert logic values for a row address strobe (“RAS”), column address strobe (“CAS”), write enable and chip select. For example, in order to read or write to a particular memory location in the memory device 10, the test system 120 asserts particular logic values on each of the bit lines 335. The logic circuitry 310 has a command input 304 coupled to the bit lines 335 for monitoring signals thereon to determine the presence of the read, write and other commands.

In the illustrated embodiment, logic circuitry 310 also includes an input 302 to receive a request signal from the third switch 340 to validate the test system 120. Logic circuitry 310 also includes a reset input 308 for receiving a reset command. The reset command initializes the logic circuitry 310. The clock 350 input of logic 310 is for controlling the timing and synchronization of data. The clock 350 frequency is selectable depending on the timing characteristics of the memory device 110. The logic 310, of course, also has a power supply input 309 for receiving power.

Herein, reference is made to “first data” and “second data” on a bit line, such as bit line 202 of bus 115 (FIG. 2A). This should be understood as follows. The logic circuitry 310 is operable to switch the operating state of the first and second switches 320 and 330 from “normal” states to “error injection” states responsive to receiving the command input 304. The logic circuitry 310 controls the operating state of the first switch 320 by asserting or de-asserting a signal on the first output 312. The second switch 330 operates in similar fashion, controlled by a signal asserted or de-asserted on output 314. The first data includes at least one data bit, with each data bit having a binary logic state. With the output 312 asserting its output signal, switch 320 is forced to an open state, referred to as the “error injection state,” which interrupts a transfer of the so-called first data. Similarly, on de-assertion, the first output 312 switches the first switch 320 to a closed state, i.e., the normal state. In the normal state, the closed position of the first switch 320 permits unimpeded data transfer on the bit line 202 of the bus 115. In the error injection state, the closed position of the second switch 330 sends what is referred to herein as “second data” to the test system on the bit line 202 included in the bus 115 via a Dₒᵤₜ node 331. The second data includes at least one data bit, with each data bit having a binary logic state. With the second switch 330 open, i.e., in the normal state, unimpeded data transfer is permitted on the bit line 202. The logic circuitry 310 potentially injects error when the first and second switches 320 and 330 are switched to their respective error injection states and, in response, the test system 120 receives the one or more data bits of the second data instead of corresponding one or more data bits of the first data.

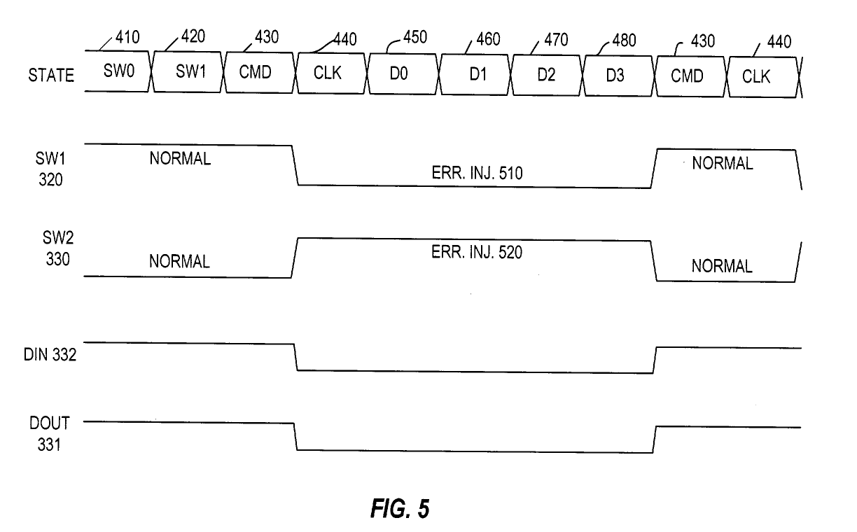

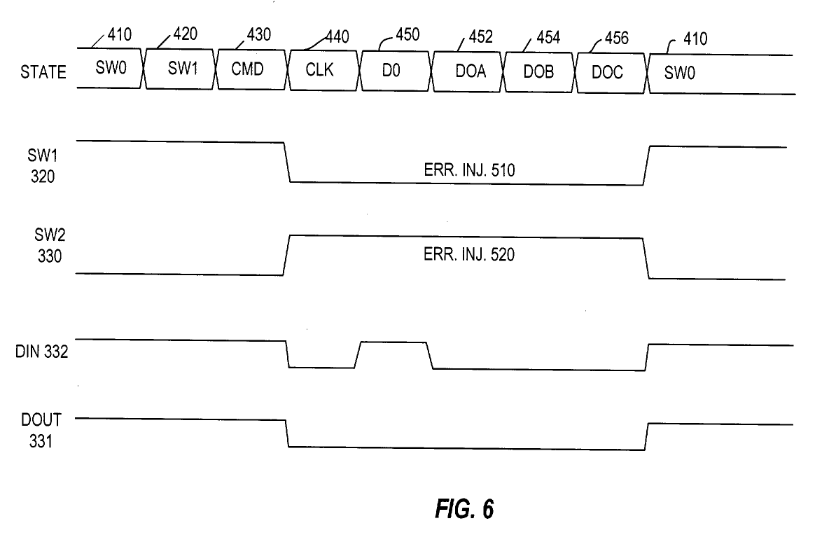

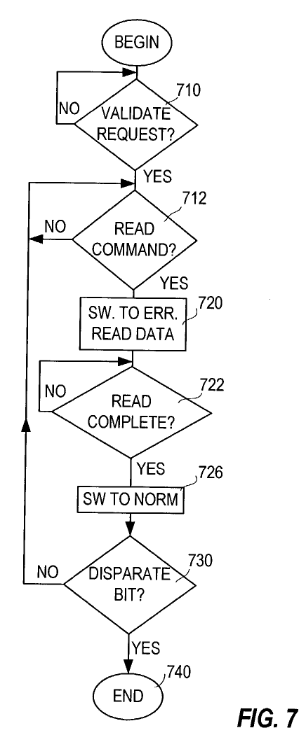

(Further details describing various operating states of the test validation system 300 are described in FIG. 4. Timing diagrams for injecting an error by controlling the operating states of the first and second switches 320 and 330 are described in FIGS. 5 and 6. Additional details of an error injection method including an error injecting sequence is described in FIG. 7.)

The first and second switches 320 and 330 shown in FIG. 3 are implemented using field effect transistor (“FET”) technology in a preferred embodiment. The FET switches typically have a resistance of 10 ohms or less and present a low capacitive load. This results in FET switches having negligible time delays compared to active component based circuits. In addition, the FET switches may be switched on or off much faster than a clock period. The preferred embodiment thus advantageously improves performance of the test validation system 300 by eliminating delays caused due to active components such as the exclusive OR gate 220 (FIG. 2A) conventionally used for error injection. As described earlier, the first switch 320 is operable to isolate the memory device 110 from the test system 120, and the second switch 230 is operable to generate a logic “0” that is transferred to the test system 120 via the Dₒᵤₜ node 331. The first and second switches 320 and 330 thus advantageously inject an error without introducing a substantial delay in the bit line 202 data path.

FIG. 4 shows detail of a state machine 400, according to an embodiment of the present invention. In one embodiment, the functions performed by the state machine 400 are implemented in the logic circuitry 310. The state machine 400 controls operating states of test validation system 300, most notably the states of the first and second switches 320 and 330 described above. The internal state machine 400 also defines a sequence of transitions among the various operating states, based on occurrence of certain events, conditions and a clock signal received on the clock input 350.

On initialization or after receiving a reset command at the reset input 308, the state machine 400 enters an idle state “SWO” 410. In the idle state 410, the machine 400 monitors status of the input 302 from switch 340. In response to the third switch 340 being activated, a validation request signal is asserted and received by the third input 302 to indicate a request to validate the test system 120. In response the request signal the state machine 400 transitions to a debounce state “SWI” 420 (not to be confused with the physical switch SWI 320 of FIG. 3). The debounce state 420 is a transitionary state that allows for debounce filtering of the request signal. The debounce state 420 then transitions to a command state 430 coinciding with a rising or falling edge of the clock signal (not shown) on clock input 350.

In the command state 430, the state machine 400 monitors the command input 304 for an indication of a read command being transferred on the bit lines 335. In response to receiving the command input 304, the state machine 400 briefly transitions through a delay state 440 and then enters a check bit-one state 450. Prior to exiting the command state 430, the state machine 400 switches the first and second switch 320 and 330 to their respective error injection states (not shown). The delay state 440 causes a clock delay (not shown) of a predefined time interval to compensate for the CAS latency time of the memory device 110. Additional details of the timing aspect of the transitions are described in FIGS. 5 and 6.

In the illustrated embodiment, the first data received by the data input 306 includes four data bits that are indicative of four consecutive data bits returned by the memory device 110. In the check bit-one state 450, a binary status check is made of the first bit of the first data received from the Dᵢₙ node 332 (FIG. 3), i.e., a portion of the bit line 202 at the memory device 110, in response to the read command received in the command state 430. Recall that with the second switch 330 operating in the error injection state, second data is sent to the test system 120 at the Dₒᵤₜ node 331 (FIG. 3) instead of first data, and the data bits of the second data all have logic state “0.” Consequently, if the first one of the bits of the first data has a logic “I” state then the state machine 400 has been successful in inserting an error. That is, in such a case the respective first bits of the first and second data are disparate and the test system 120 will receive a logic “0” bit in the first bit of the second data instead of the logic “1” bit that the system 120 expects in the first bit of the first data. In such a case, a transition is made to the idle state 410 via dummy transition states 452, 454 and 456.

If the status check of the first bit of the first data detects a logic “0” then this indicates that the first bits were not disparate, so the state machine 400 transitions to check the second bit of the first data, referred to as a check bit-two state 460. If the status check of the second bit of the first data detects a logic “1” then the state machine 400 transitions to the idle state 410 via dummy transition states 462 and 464. If necessary, the process is repeated at check bit-three state 470, and check bit-four state 480 for the third and fourth bits respectively of the data input 306.

If the status checking proceeds all the way through checking the fourth bit and detects a logic “0” for all four bits, then this indicates the state machine 400 did not inject an error, so a transition is made to the command state 430 to again monitor the command input 304.

In the embodiment illustrated, the state machine 400 switches the switches 320 and 330 back to their normal states after four bits. Accordingly, the dummy transition states 452, 454, 456, 462, 464 and 472 are used, if necessary, for timing purposes, i.e., so that the switching back to normal occurs independently of the values of the four bits. That is, in the embodiment the state machine 400 does not read bit values once it is determined that one of the bits read is different than one of the bits injected. In such a case, in the dummy states the state machine 400 merely waits for remaining bits of the four bit series, but does not necessarily read their bit values.

FIGS. 5 and 6 illustrate timing diagrams for injecting an error by controlling the operating states of the first and second switches 320 and 330. FIG. 5 illustrates a timing diagram for an example in which an error is not successfully injected. In this instance, an error injection request is received in the idle state 410 and the read command input 304 is received in the command state 430. At the end of the command state 430 and coinciding with the clock 350 cycle, the first switch 320 is turned off (switched to an open, error injection state 510) and the second switch 330 is turned on (switched to a closed, error injection state 520). In response, the Dₒᵤₜ node 331 transitions to logic “0”. After transitioning through the delay state 440, the first bit of the first data is received as the input data input 306 (shown coupled to the Dᵢₙ node 332). Each of the four bits of the first data is checked for a logic “1” in the next four cycles of the clock 350. In this example, however none of the four bit values returned by the memory device 110 included a logic “1” value. As a result no error has been injected. As described earlier, at this point the state engine 400 transitions to the command state 430 to monitor the next read command and repeat the cycle.

FIG. 6 illustrates a timing diagram for an example where an error is successfully injected. In this instance, an error injection request is received in the idle state 410 and a read command input is received in the command state 430. At the end of the command state 430 and coinciding with the clock 350 cycle, the first switch 320 is switched to the error injection state 510 and the second switch 330 is switched to the error injection state 520. In response, the Dₒᵤₜ node 331 transitions to logic “0”. After transitioning through the delay state 440, the first bit of the first data is received as the input data input 306 (shown coupled to the Dᵢₙ node 332). Each of the four bits of the first data is checked for a logic “1” in the next 4 cycles of the clock 350. In this embodiment, in the check bit-one state 450 the first bit of the four bit first data values returned by the memory device 110 included a logic “1” value. This indicates that an error has successfully been injected. After waiting for the remaining bits of the first data in respective states 452, 454 and 456, the state engine 400 transitions to the idle state 410 to monitor the next request validation and repeat the cycle.

Referring to FIG. 7, a method for controlling an error injection sequence is shown in a flow chart format, according to an embodiment of the present invention. Note that various steps of FIG. 7 may be added, omitted, combined, altered, or performed in different sequences than depicted herein. Note also that in some respects the flow chart of FIG. 7 depicts logic of an embodiment of the invention in less detail, and thus in a more simplified form, than what is depicted in the state diagram of FIG. 4.

The logic circuitry 310 (FIG. 3) begins an error injection sequence at 710 responsive to first receiving a signal on input 302 requesting that the test system 120 be validated. Then, at 712, the logic circuitry 310 monitors for signals on the command input 304 indicating a read command sent to memory by the test system on the bit lines 335. In step 720, responsive to detecting the read command, the first and second switches 320 and 330 are switched to their respective error injection states and first data is read. That is, as described earlier, the error injection state of the first switch 320 interrupts a transfer of first data on the bit line 202 of the bus 115, and the error injection state of the second switch 330 sends second data to the test system 120 on the bit line 202 of the bus 115. Thus, in this mode the test system 120 receives the one or more data bits of the second data instead of corresponding one or more data bits of the first data.

In step 722 the logic circuitry 310 waits until the end of a predefined number of cycles of the clock signal received on clock input 350 (as illustrated in FIGS. 5 and 6), which corresponds to time for reading a predetermined number of bits. Then, after the read sequence is complete at 722, at 726 the first and second switches 320 and 330 are switched to their respective normal states. In step 730, first data (read in step 720) is checked to determine whether at least one of the corresponding data bits of the first and second data have disparate binary logic states, as described in the operation of the check bit states 450, 460, 470 and 480 herein above. If no disparate binary logic states are detected, then step 730 branches back to step 712 to await another read command, and the error injection sequence repeats steps 712 through 730. If disparate logic states are detected, then step 730 branches to end the error injection sequence at step 740.

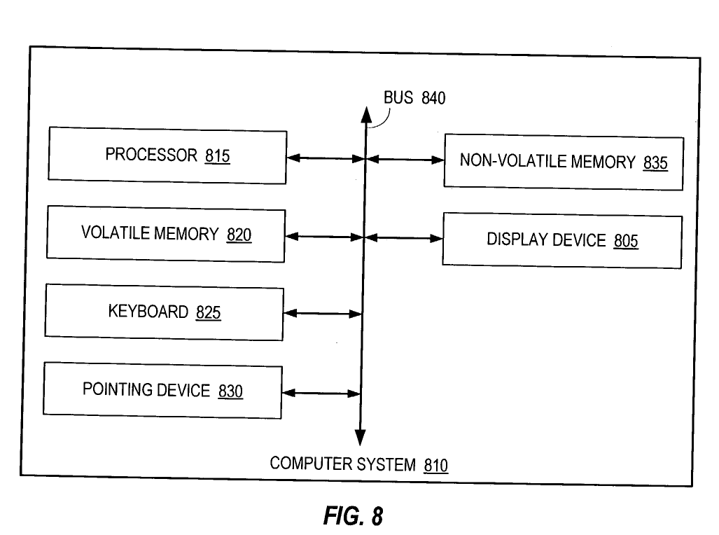

Referring to FIG. 8, a computer system 810 is shown that is generally applicable for the various embodiment described according to the present invention. The system 810 includes a processor 815, a volatile memory 820, e.g., RAM, a keyboard 825, a pointing device 830, e.g., a mouse, a nonvolatile memory 835, e.g., ROM, hard disk, floppy disk, CD-ROM, and DVD, and a display device 805 having a display screen. Memory 820 and 835 are for storing program instructions which are executable by processor 815 to implement various embodiments of a method in accordance with the present invention. Components included in system 810 are interconnected by bus 840. A communications device (not shown) may also be connected to bus 840 to enable information exchange between system 810 and other devices.

In various embodiments system 810 takes a variety of forms, including a personal computer system, mainframe computer system, workstation, Internet appliance, PDA, an embedded processor with memory, etc. In one embodiment, the logic circuitry 310 is implemented in a commercially available programmable array logic (“PAL”) chip. In an alternative embodiment, the logic circuitry 310 may be implemented in the test system 310 for self-validation. In yet another alternative embodiment, the logic circuitry 310 may be implemented using commercially available chips such as gates, flip-flops and timers, or using an application specific integrated circuit. In yet another alternative embodiment, the logic circuitry 310 may be implemented as an embodiment of system 810.

That is, it should be understood that the term “computer system” is intended to encompass any device having a processor that executes instructions from a memory medium. The memory medium preferably stores instructions (also known as a “software program”) for implementing various embodiments of a method in accordance with the present invention. In various embodiments the one or more software programs are implemented in various ways, including procedure-based techniques, component-based techniques, and/or object-oriented techniques, among others. Specific examples include XML, C++ objects, Java and Microsoft Foundation Classes (MFC).

The description of the present embodiments have been presented for purposes of illustration, but are not intended to be exhaustive or to limit the invention to the forms disclosed. Many additional aspects, modifications and variations are also contemplated and are intended to be encompassed within the scope of the following claims. For example, logic circuitry 310 has been shown in FIG. 3 as separate from the memory device 110 and test system 120. It should be understood, however, that the circuitry 310 may also be incorporated into the test system 120. For example, the test system 120 may include a computer system, such as shown in FIG. 8, and the circuitry 310 may be included in the computer system 810, such as, for example, in a memory controller or bus controller thereof. Likewise, the circuitry 310 may also be incorporated into the memory device 110. Furthermore, while the memory device 110 has been described as a target device having a memory, it should be understood that the memory device 110 may include a memory controller, and therefore testing the memory device by the test system includes testing the memory controller in the memory device 110. Accordingly, injecting errors by the logic circuitry 310 may include injecting errors in data transmitted between the test system 120 and the memory controller in the memory device 110.

In another example, while certain aspects of the present invention have been described in the context of a single data rate memory chip, those of ordinary skill in the art will appreciate that the processes of the present invention are capable of being applied to a variety of IC's, including double data rate (“DDR”) memory chips. As another example, the processes of the present invention may be used to inject write errors by monitoring for write commands instead of read commands, intercepting first data from the system 120 to the memory device 110 and writing second data in its place. Also, logical “1's” can be written instead of “0's” by tying switch 330 to Vcc instead of ground. In still another embodiment, multiple, parallel-bit errors are injected by the logic circuitry 310, in which case additional instances of switches 320 and 330 are required for each additional bit line into which an error is injected.

It should also be appreciated that according to an embodiment described above, it is considered sufficient to inject merely one erroneous bit in the binary data being transferred on the bit line 202. Alternatively, more complex state machine can search for a more complicated seed pattern in the first data, i.e., the data that is read from memory, so as to ensure that a more complicated error is injected in the second data, i.e., the data that is sent to the test system. For example, in another embodiment, such as for a case in which an apparatus under test is more complex, the state machine 400 checks to determine if the first data includes a certain pre-defined serial sequence of logic ones or zeros or combination thereof, in order to confirm that an error has been positioned on specific data that was generated by the test program executing in the test system 120 and that was written by the test program to the memory 110. By specifying a sufficiently complex or long seed pattern, or both, it becomes almost one-hundred percent certain that the pattern is one that the test program wrote to the memory 110 in order to test the memory 110, and not merely a pattern that happened by chance to occur due to some other cause. Thus, by programming the test program to write a sufficiently complex or long predetermined seed pattern, and by linking the software memory test to the described error injecting apparatus in the above manner, the test system 120 can be validated without the necessity of the error injecting logic 310 examining memory addresses. Furthermore, a test pattern can be chosen that is known not to correspond to any architected instruction conventionally sent to the memory device 110. This further ensures that the pattern detected by the logic 310 is one that test program in test system 120 wrote to the memory 110 in order to test the memory 110, and not an instruction. Consequently, logic 310 can advantageously operate independently of, and with no knowledge of, memory 110 addresses.

In another variation, consider that it has been described herein above that the state machine 400 checking data bits to determine whether first data, i.e., the data read from memory 110 by the logic circuitry 310, and second data, i.e., the data injected to the test system 120 in place of the first data, have any disparate bits. And in an embodiment it has been described that this checking by the state machine 400 is done while the switches 320 and 330 are in their error injection states. In an alternative embodiment, some or all of the checking is done after the switches 320 and 330 are returned to their normal, non-disruptive states.

Also, the processes of the present invention are capable of being distributed in the form of a computer readable medium of instructions in a variety of forms. The present invention applies equally regardless of the particular type of signal bearing media actually used to carry out the distribution. Examples of computer readable media include RAM, flash memory, recordable-type media such as a floppy disk, a hard disk drive, a ROM, CD-ROM, DVD and transmission-type media such as digital and/or analog communication links, e.g., the Internet.

To reiterate, many additional aspects, modifications and variations are also contemplated and are intended to be encompassed within the scope of the following claims. Moreover, it should be understood that in the following claims actions are not necessarily performed in the particular sequence in which they are set out.

What is claimed is:

1. An apparatus comprising:
a data input for receiving data from a memory device being tested by a test system, the test system being coupled to the memory device by a bus;
a command input for receiving an indication of a command sent to the memory device;
a first switch operable in an error injection state and a normal state, wherein in the error injection state the first switch interrupts a transfer of first data on the bus from the memory device to the test system, the first data including a series of data bits, such a data bit having a binary logic state, and in the normal state the first switch permits unimpeded data transfer on the bus;
a second switch operable in an error injection state and a normal state, wherein in the error injection state the second switch sends second data to the test system on the bus, wherein the second data includes a series of data bits, and with the first and second switches in their respective error injection states the test system receives the bits of the second data instead of corresponding bits of the first data; and
logic circuitry operable to read the first data on the data input and control an error injection sequence, wherein the sequence includes the steps of:
a) switching the first and second switches from their respective normal states to their respective error injection states responsive to receiving the command; and
b) switching the first and second switches back to their respective normal states, wherein the logic circuitry is operable to control steps a) and b) independently of the logic states of the bits of the first data.

2. The apparatus of claim 1, comprising:
a third switch operable to generate a request to the logic circuitry to validate the test system.

3. The apparatus of claim 1, wherein the sequence includes the step of ending the sequence responsive to determining that at least one of the corresponding data bits of the first and second data have disparate binary logic states.

4. The apparatus of claim 3, wherein the data bits of the second data all have a certain binary logic state, and the error injection sequence includes:
repeating steps a) and b) responsive to determining that all the data bits of the first data have the same certain binary logic state.

5. The apparatus of claim 1, comprising:
a clock input, wherein the logic circuitry times the switching of the first and second switches to their error injection states responsive to a clock signal received on the clock input.

6. The apparatus of claim 1, wherein the first data includes a series of four data bits read by the logic circuitry from the memory.

7. The apparatus of claim 1, wherein the command is a read command.

8. A method for generating an error to validate a test system, the method comprising:
receiving an indication of a test system operation wherein data is transferred on a bus between a memory and the test system;
switching first and second switches to respective error injection states responsive to receiving the indication of the test system operation, wherein in the error injection states the first switch interrupts a transfer of first data on the bus between the memory device and the test system, the first data including a series of data bits, such a data bit having a binary logic state, and the second switch sends second data to the test system on the bus, wherein the second data includes a series of data bits, so that with the first and second switches in their respective error injection states the test system receives the series of bits of the second data instead of corresponding bits of the first data; and
reading the logic states of the first data, wherein a sequence, in which the first and second switches are switched from their respective normal states to their respective error injection states and back to their normal states, is independent of the states of the bits of the first data.

9. The method of claim 8, comprising:
generating a request by a third switch to the logic circuitry to validate the test system.

10. The method of claim 8, wherein the sequence includes the step of ending the sequence responsive to determining that at least one of the corresponding data bits of the first and second data have disparate binary logic states.

11. The method of claim 10, wherein the data bits of the second data all have a certain binary logic state, and the error injection sequence includes:
repeating steps a) and b) responsive to determining that all the data bits of the first data have the same certain binary logic state.

12. The method of claim 8, comprising timing the switching of the first and second switches to their error injection states by the logic circuitry responsive to a clock signal received on a clock input.

13. The method of claim 8, wherein the first data includes a series of four data bits read by the logic circuitry from the memory.

14. The method of claim 8, wherein the command is a read command.

15. A computer program product for generating an error to validate a test system, the computer program product comprising:
instructions for receiving an indication of a test system operation wherein data is transferred on a bus between a memory and the test system;
instructions for switching first and second switches to respective error injection states responsive to receiving the indication of the test system operation, wherein in the error injection states the first switch interrupts a transfer of first data on the bus between the memory device and the test system, the first data including a series of data bits, such a data bit having a binary logic state, and the second switch sends second data to the test system on the bus, wherein the second data includes a series of data bits, so that with the first and second switches in their respective error injection states the test system receives the series of bits of the second data instead of corresponding bits of the first data; and
instructions for reading the logic states of the first data; and
instructions for controlling a sequence, in which the first and second switches are switched from their respective normal states to their respective error injection states and back to their normal states, independently of the states of the bits of the first data.

16. The computer program product of claim 15, comprising:
instructions for generating a request by a third switch to the logic circuitry to validate the test system.

17. The computer program product of claim 15, wherein the instructions for controlling the sequence include instructions for ending the sequence responsive to determining that at least one of the corresponding data bits of the first and second data have disparate binary logic states.

18. The computer program product of claim 17, wherein the data bits of the second data all have a certain binary logic state, and the error injection sequence includes:
repeating steps a) and b) responsive to determining that all the data bits of the first data have the same certain binary logic state.

19. The computer program product of claim 15, comprising instructions for timing the switching of the first and second switches to their error injection states by the logic circuitry responsive to a clock signal received on a clock input.

20. The computer program product of claim 15, wherein the first data includes a series of four data bits read by the logic circuitry from the memory.

21. The computer program product of claim 15, wherein the command is a read command.
